(19) United States
(12) Patent Application Publication
(10) Pub. No.: US 2026/0190582 A1
(43) Pub. Date: Jul. 2, 2026

(54) WEARABLE DISPLAY DEVICE AND ELECTRONIC DEVICE USING THE SAME

(71) Applicant: Samsung Display Co., Ltd., Yongin-si (KR)

(72) Inventors: Dong Hyun KIM, Yongin-si (KR); Young Seok SEO, Yongin-si (KR)

(21) Appl. No.: 19/322,897

(22) Filed: Sep. 9, 2025

(30) Foreign Application Priority Data
Jan. 2, 2025 (KR) 10-2025-0000387

(51) Int. Cl. H10H 29/80; G06F 1/16; H02S 20/30; H10H 29/85

(52) U.S. Cl. CPC H10H 29/8321; G06F 1/163; H02S 20/30; H10H 29/8506

(57) ABSTRACT

A wearable display device includes a top cover having a ring shape or a cylindrical shape with respect to a curvature axis parallel to a first direction, a display member having a curvature along an inner side of the top cover and having a plurality of light emitting elements, a battery member in an inner side of the top cover and having a curvature, the battery member including a photovoltaic panel and a connection member in the inner side of the top cover and having a curvature, the connection member being located between the display panel and the photovoltaic panel, and including a plurality of dummy elements.

### CROSS-REFERENCE TO RELATED APPLICATION

This application claims priority to and the benefit of Korean Patent Application No. 10-2025-0000387, filed on Jan. 2, 2025, in the Korean Intellectual Property Office, the entire disclosure of which is incorporated by reference herein.

### BACKGROUND

### 1. Field

The present disclosure relates to a wearable display device including a photovoltaic cell and an electronic device using the same.

### 2. Description of the Related Art

Electronic devices such as smart rings, smart watches, smartphones, tablets, and laptops that may provide various functions to users while being worn or carried are widely used. These electronic devices may include various electronic components to provide various functions to users. The electronic components of the electronic devices may be powered by batteries included inside the electronic devices. As electronic devices become smarter, battery consumption is increasing due to the increased use of biosignal sensing, communications, and applications, as well as increased display size, resolution, and central processing unit (CPU) performance.

Because conventional ring-type display devices have limitations in size, they also have limitations in battery size. When using conventional batteries, there is the inconvenience of having to charge them frequently to cope with the increasing battery consumption. However, in the case of ring-type display devices, if it is difficult to charge them while they are worn, it is also inconvenient for users to attach and detach them compared to other wearables.

### SUMMARY

The present disclosure has been conceived in consideration of these points, and one or more embodiments of the present disclosure may provide to enable battery charging while wearing the ring-type display device by including a solar cell and a display panel in the ring-type display device.

However, aspects and features of embodiments of the present disclosure are not restricted to the one set forth herein. The above and other aspects and features of embodiments of the present disclosure will become more apparent to one of ordinary skill in the art to which the present disclosure pertains by referencing the detailed description of the present disclosure given below.

According to one or more embodiments, a wearable display device includes a top cover having a ring shape or a cylindrical shape with respect to a curvature axis parallel to a first direction, a display member having a curvature along an inner side of the top cover and having a plurality of light emitting elements, a battery member in an inner side of the top cover and having a curvature, the battery member including a photovoltaic panel and a connection member in the inner side of the top cover and having a curvature, the connection member being located between the display panel and the photovoltaic panel, and including a plurality of dummy elements.

The plurality of light emitting elements are connected to each other by a hinge, and wherein the hinge includes a material that is flexible and conductive.

The light emitting element includes a first semiconductor layer doped with a first conductive dopant, a second semiconductor layer doped with a second conductive dopant, and an active layer disposed between the first semiconductor layer and the second semiconductor layer, wherein the display member further includes a common electrode on the light emitting element, and wherein the hinge is connected to the common electrode.

The plurality of dummy elements are connected to each other by the hinge, and wherein the dummy elements are connected to the adjacent light emitting elements by the available hinge.

The plurality of dummy elements includes a first semiconductor layer doped with a first conductive dopant, a second semiconductor layer doped with a second conductive dopant, and an active layer between the first semiconductor layer and the second semiconductor layer.

The battery member further includes a rechargeable battery.

The photovoltaic panel is in the an inner side of the top cover and has a curvature, the photovoltaic panel includes a first electrode, a second electrode located opposite the first electrode, a semiconductor layer interposed between the first electrode and the second electrode, and an anti-reflective film on the semiconductor layer and adjacent to the top cover.

The first electrode and the second electrode include a conductive material.

The first electrode includes a same material as the hinge.

The display member includes a first display area having a first curvature and a second display area having a second curvature, wherein the first curvature is greater than the second curvature.

A first gap between pixels of the first display area in a same column is smaller than a second gap between pixels of the second display area.

A density of pixels of the first display area in a same column is greater than a density of pixels of the second display area.

A gap between pixels of the display ember increases and a density of the pixels decreases as a distance from a center line of the first display area and the second display area increases.

The device further includes an inner ring having a ring shape or a cylindrical shape with respect to the curvature axis.

The display member and the battery member are wound around the inner ring.

The common electrode includes a transparent conductive material.

The light emitting element further includes a first insulating layer around side surfaces of the light emitting element and a connection electrode, a reflective layer on the side surfaces of the light emitting element, and a second insulating layer around the side surfaces of the light emitting element and the connection electrode, the second insulating layer being on the reflective layer and the first insulating layer.

The display member further includes a lens-shaped optical structure on a light emitting element layer on the light emitting element.

According to one or more embodiments, an electronic device including: a memory; a processor configured to execute an application stored by the memory; and a wearable display device, wherein the wearable display device includes: a top cover having a ring shape or a cylindrical shape with respect to a curvature axis parallel to a first direction; a display member having a curvature along an inner side of the top cover and having a plurality of light emitting elements; a battery member in an inner side of the top cover and having a curvature, the battery member including a photovoltaic panel; and a connection member in the inner side of the top cover and having a curvature, the connection member being located between the display panel and the photovoltaic panel, and including a plurality of dummy elements.

The display member includes a first display area having a first curvature and a second display area having a second curvature, wherein the first curvature is greater than the second curvature.

The wearable display device according to embodiments of the present disclosure may enhance convenience by enabling photovoltaic charging while worn on the user's body.

However, the effects, aspects, and features of embodiments of the present disclosure are not limited to the aforementioned effects, aspects, and features, and various other effects, aspects, and features are included in the present specification.

### BRIEF DESCRIPTION OF THE DRAWINGS

FIG. 1 is a perspective view illustrating an application example of a wearable display device according to one or more embodiments.

FIG. 2 is an exploded perspective view of a wearable display device according to one or more embodiments.

FIG. 3 is a top view of a first embodiment illustrating a structure in which the display member, battery member, and connection member shown in FIG. 2 are spread out flat.

FIG. 4 is an enlarged view of an area A of FIG. 3.

FIG. 5 is a cross-sectional view illustrating an embodiment corresponding to the line I-I′ of FIG. 4.

FIG. 6 is a cross-sectional view illustrating a state in which the display panel of FIG. 5 is curved to have a curvature.

FIG. 7 is a cross-sectional view illustrating a light-emitting element according to one or more embodiments.

FIG. 8 is a diagram illustrating a structure of a photovoltaic panel according to one or more embodiments.

FIG. 9 is a cross-sectional view illustrating a cross-sectional structure of one direction of the wearable display device shown in FIG. 1 according to one or more embodiments.

FIG. 10 is a top view illustrating a structure in which the display panel of FIG. 9 is spread out flat.

FIG. 11 is a block diagram of an electronic device according to one or more embodiments of the present disclosure.

### DETAILED DESCRIPTION

The embodiments will now be described more fully hereinafter with reference to the accompanying drawings. The embodiments may, however, be provided in different forms and should not be construed as limiting. The same reference numbers indicate the same components throughout the present disclosure. In the accompanying figures, the thickness of layers and regions may be exaggerated for clarity.

Some of the parts which are not associated with the description may not be provided in order to describe embodiments of the present disclosure.

It will also be understood that when a layer is referred to as being “on” another layer or substrate, it can be directly on the other layer or substrate, or intervening layers may also be present. In contrast, when an element is referred to as being “directly on” another element, there may be no intervening elements present.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art. The expression “not overlap” may include meaning such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

The spatially relative terms “below,” “beneath,” “lower,” “above,” “upper,” and/or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

When an element is referred to as being “connected” or “coupled” to another element, the element may be “directly connected” or “directly coupled” to another element, or “electrically connected” or “electrically coupled” to another element with one or more intervening elements interposed therebetween. It will be further understood that when the terms “comprises,” “comprising,” “has,” “have,” “having,” “includes” and/or “including” are used, they may specify the presence of stated features, integers, steps, operations, elements and/or components, but do not preclude the presence or addition of other features, integers, steps, operations, elements, components, and/or any combination thereof.

It will be understood that, although the terms “first,” “second,” “third,” and/or the like may be used herein to describe various elements, these elements should not be limited by these terms. These terms are used to distinguish one element from another element or for the convenience of description and explanation thereof. For example, when “a first element” is discussed in the description, it may be termed “a second element” or “a third element,” and “a second element” and “a third element” may be termed in a similar manner without departing from the teachings herein.

The terms “about” or “approximately” as used herein is inclusive of the stated value and means within an acceptable range of deviation for the particular value as determined by one of ordinary skill in the art, considering the measurement in question and the error associated with measurement of the particular quantity (for example, the limitations of the measurement system). For example, “about” may mean within one or more standard deviations, or within ±30%, 20%, 10%, 5% of the stated value.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.” In the specification and the claims, the phrase “at least one of” is intended to include the meaning of “at least one selected from the group of” for the purpose of its meaning and interpretation. For example, “at least one of A and B” may be understood to mean “A, B, or A and B.”

Unless otherwise defined or implied, all terms used herein (including technical and scientific terms) have the same meaning as commonly understood by those skilled in the art to which this disclosure pertains. It will be further understood that terms, such as those defined in commonly used dictionaries, should be interpreted as having a meaning that is consistent with their meaning in the context of the relevant art and will not be interpreted in an ideal or excessively formal sense unless clearly defined in the specification.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Hereinafter, embodiments of the present disclosure are described with reference to the drawings.

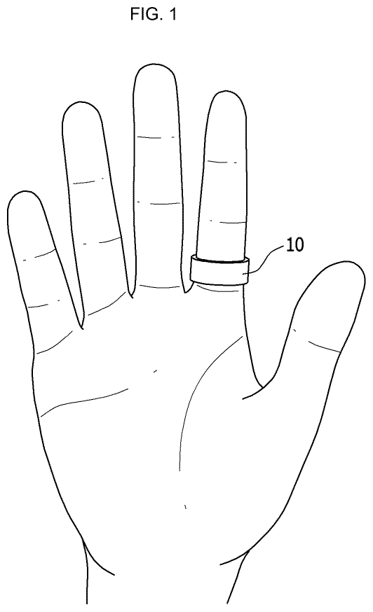

FIG. 1 is a perspective view illustrating an application example of a wearable display device according to one or more embodiments.

Referring to FIG. 1, a wearable display device 10 according to one or more embodiments may be used in electronic devices that are formed to be wearable on a user's body in a ring or cylinder type, such as a ring, bracelet, smart watch, band, watch phone and/or the like. Accordingly, the wearable display device 10 according to one or more embodiments may also be referred to a smart ring.

The organic light-emitting diode, a quantum dot light-emitting display device including a quantum dot light-emitting layer, an inorganic light-emitting display device including an inorganic semiconductor, and an ultra-small light-emitting display device using a micro or nano light emitting diode (micro LED or nano LED). Hereinafter, the display device 10 is described mainly as an ultra-small light-emitting display device, but the present disclosure is not limited thereto. Meanwhile, for the convenience of explanation, an ultra-small light-emitting diode is described as a light-emitting element below.

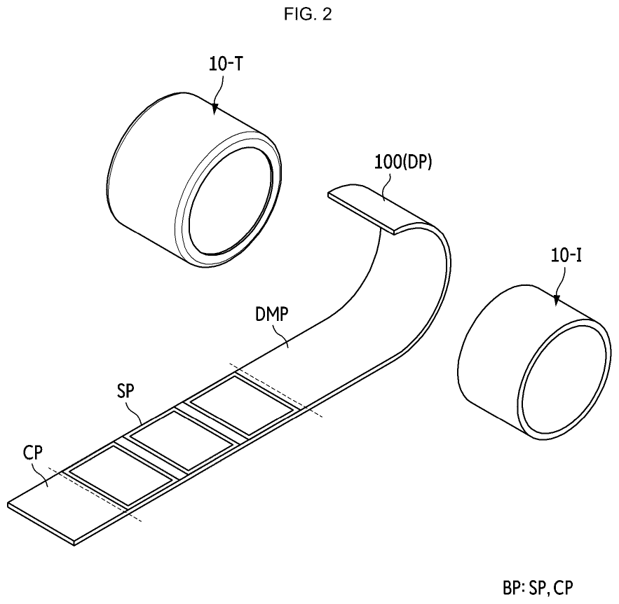

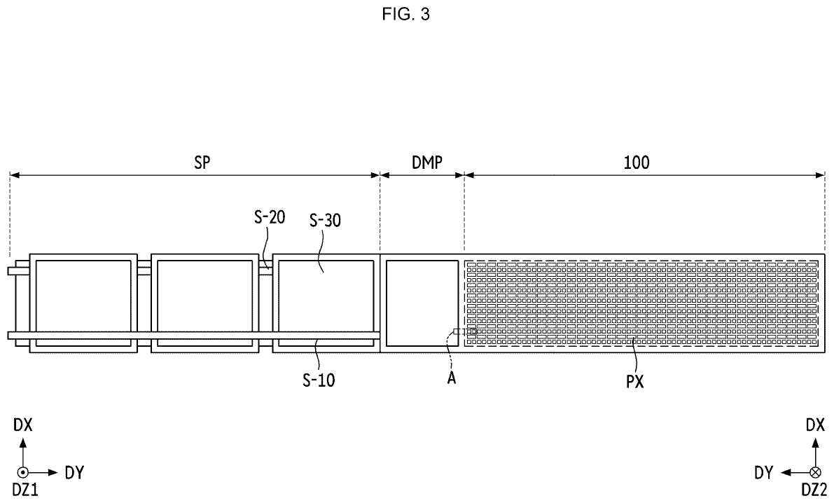

FIG. 2 is an exploded perspective view of a wearable display device according to one or more embodiments. FIG. 3 is a top view of a first embodiment illustrating a structure in which the display member, battery member, and connection member shown in FIG. 2 are spread out flat.

Referring to FIGS. 2 and 3, the wearable display device 10 according to one or more embodiments may include an inner ring 10-I, a display member 100, a battery member BP, a connection member DMP, and a top cover 10_T. However, the components of the wearable display device 10 according to one or more embodiments are not limited thereto, and components according to one or more embodiments may be added or at least one component may be omitted.

The inner ring 10-I is disposed on the inner side of the display member 100, the battery member BP, the connection member DMP, and the top cover 10_T. The inner ring 10-I is a part that is worn on a user's finger. The inner ring 10-I may be formed in a ring or cylindrical shape overall. The inner ring 10-I may include a conductor material.

The display member 100 may be wrapped around the outside (e.g., an outer peripheral surface) of the inner ring 10-I. The display member 100 includes a display panel DP having a plurality of pixels PX and may output an image by emitting light in the outer direction of the top cover 10_T.

The display member 100 may further include a main driving circuit, a scan driving portion, a circuit board, and/or the like for driving the display panel DP.

The battery member BP supplies power for operation the wearable display device 10. For example, the battery member BP supplies power for the display panel DP to output an image.

The battery member BP may be wrapped around the outside (e.g., the outer peripheral surface) of the inner ring 10-I. The battery member BP may include a flexible material so that it may be bent and/or rolled.

The battery member BP may include a photovoltaic panel SP and a rechargeable battery CP. The photovoltaic panel SP converts light energy into electrical energy and uses the photovoltaic effect that occurs when light is irradiated on the p-n junction of a semiconductor. The photovoltaic panel SP includes, for example, but is not limited to, a silicon photovoltaic cell.

The electrical energy converted by the photovoltaic panel SP may be stored by the rechargeable battery CP. In addition, the rechargeable battery CP may receive electrical energy from the outside through a terminal and store it. That is, the battery member BP may directly generate and store electrical energy through the photovoltaic panel SP or may receive energy from an external power source and store it.

The photovoltaic panel SP may include a first electrode S-10, a second electrode S-20 disposed opposite the first electrode S-10, and a semiconductor layer S-30 interposed between the first electrode S-10 and the second electrode S-20. The photovoltaic panel SP may include a flexible material so that it may be bent and/or rolled.

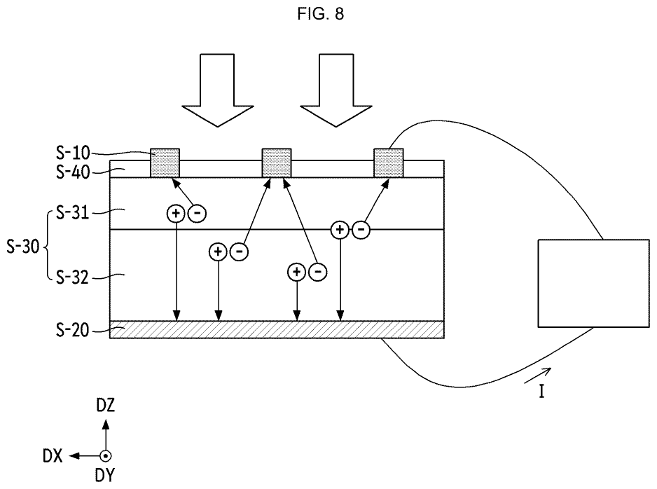

In particular, the first electrode S-10 disposed at the outermost side may include a material having greater flexibility than the second electrode S-20. The material of the first electrode S-10 may be a material having flexibility and conductivity. The first electrode S-10 may be made of, for example, graphene or a conductive polymer material. Therefore, the first electrode S-10 may be bent (e.g., easily bent) to have a curvature. The structure of the photovoltaic panel SP is described in detail with reference to FIG. 8.

The connection member DMP may be wrapped around the outer side (e.g., the outer peripheral surface) of the inner ring 10-I. The connection member DMP is disposed between the display member 100 and the battery member BP. For example, the connection member DMP is disposed between the display panel DP and the photovoltaic panel SP. It is possible to improve the reliability of the device by preventing the heat generated by the photovoltaic panel SP from being directly transferred to the display panel DP.

The top cover 10_T is formed in a ring shape or a cylindrical shape applicable to rings, bracelets, watches, bands, etc. The top cover 10_T may be combined with the inner ring I0-I on the outer side (e.g., an outer peripheral surface) of the display member 100, the battery member BP, and the connection member DMP, etc. The top cover 10_T may cover the display member 100, the battery member BP, and the connection member DMP, etc. A combination groove or combination protrusion for combination with the inner ring 10-I may be formed on the top cover 10_T. Accordingly, a combination protrusion or combination groove corresponding to the combination groove or combination protrusion of the top cover 10-T may be provided on the inner ring 10-I.

The top cover 10_T may be formed of a light-transmitting material such as glass and/or plastic.

In one or more embodiments, the main driving circuit may generate electrical signals such as control signals and data voltages for driving the display panel DP. The main driving circuit may be formed as an integrated circuit (IC) and attached to the display panel DP or a circuit board using a COG (chip on glass) method, a COP (chip on plastic) method, and/or an ultrasonic bonding method, but is not limited thereto. For example, the main driving circuit may be attached to the circuit board using a COF (chip on film) method.

The scan driving portion sequentially supplies gate scan signals to the first and second light-emitting pixels and the first and second light-sensing pixels disposed on the display member 100, thereby controlling the light-emitting driving of the first and second light-emitting pixels and the light-receiving operation of the first and second light-sensing pixels.

The scan driving portion receives a light emission control signal from the main driving circuit, and sequentially generates light emission scan signals in accordance with horizontal line driving periods according to the light emission control signal and sequentially supplies them to the first and second light emission pixels. That is, the scan driving portion sequentially controls the light emission timing of the first and second light emission pixels. In addition, the scan driving portion may sequentially generate light detection scan signals in units of horizontal line driving periods according to the scan control signal from the main driving circuit and sequentially supply them to the first and second light detection pixels. That is, the scan driving portion sequentially controls the light detection timing of the first and second light detection pixels.

A main driving circuit is mounted on a circuit board, and the main driving circuit is electrically connected to the display panel DP by the circuit board. The circuit board may be attached to one end of the display panel DP. As a result, the circuit board may be electrically connected to the display panel DP and the main driving circuit. The circuit board may be a flexible printed circuit board (FPCB), a printed circuit board (PCB), or a flexible film such as a chip on film (CoF).

According to one or more embodiments of the present disclosure, the wearable display device may charge the battery with electrical energy using solar energy, thereby extending the play time and charging cycle of the wearable display device.

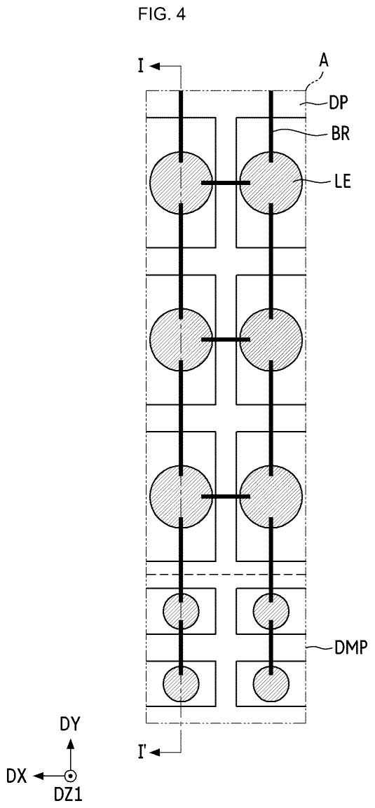

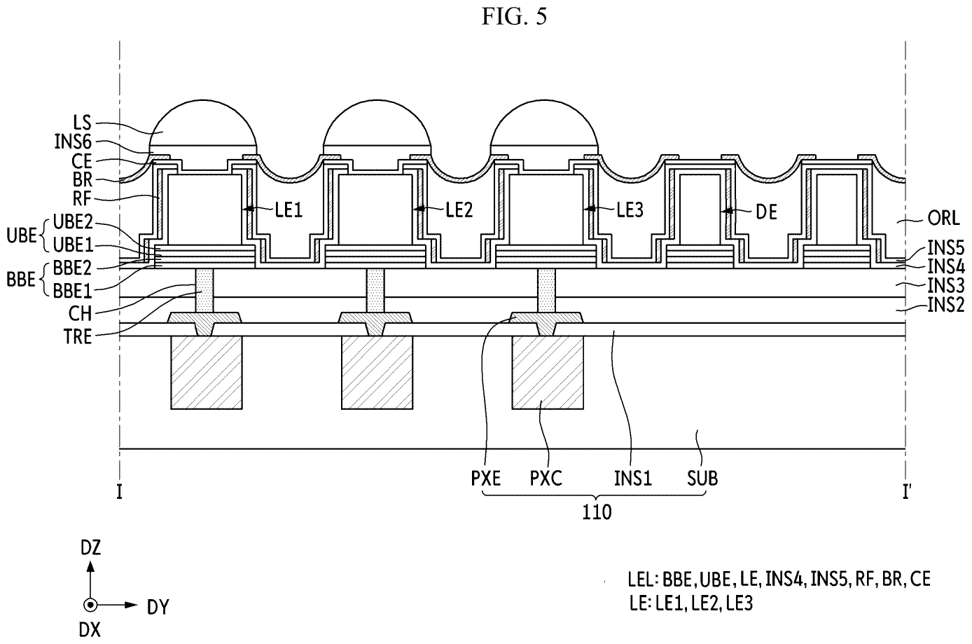

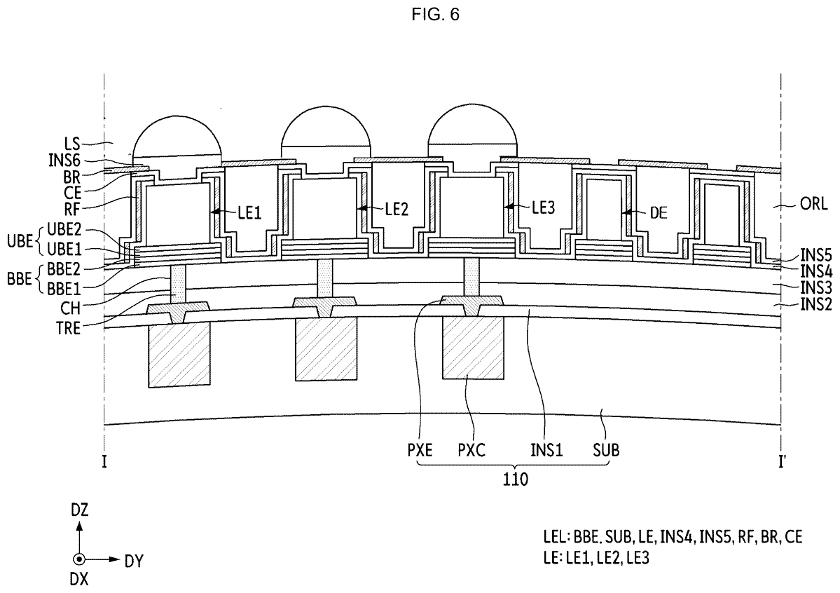

FIG. 4 is an enlarged view of an area A of FIG. 3. FIG. 5 is a cross-sectional view illustrating an embodiment corresponding to the line I-I′ of FIG. 4. FIG. 6 is a cross-sectional view illustrating a state in which the display panel of FIG. 5 is curved to have a curvature.

Referring to FIGS. 4 and 5, the display panel DP illustrates one embodiment in which light-emitting diodes are disposed as light emitting elements LE on a semiconductor circuit board (e.g., a backplane substrate SUB on which pixel circuits PXC are formed based on a silicon wafer) formed by a semiconductor process using a silicon wafer. However, the device including the light emitting elements LE according to one or more embodiments is not limited thereto. For example, the light emitting elements LE manufactured according to one or more embodiments may be applied to display devices of different types and/or structures.

The display panel DP may include a plurality of pixels PX. Each pixel PX may include at least two light emitting elements LE.

In one or more embodiments, each pixel PX may include three light emitting elements LE. For example, each pixel PX may include a first light emitting element LE1, a second light emitting element LE2, and a third light emitting element LE3. The number and/or type of light emitting elements LE provided to the pixels PX may vary depending on the embodiments.

In one or more embodiments, each pixel PX may include light emitting elements LE that emit light of different colors. For example, the first light emitting element LE1, the second light emitting element LE2, and the third light emitting element LE3 may emit light of different colors.

The first light emitting element LE1 may emit first light. The first light may be red light. For example, the main peak wavelength R-peak of the first light may be disposed at approximately 600 nm to 750 nm, but the present disclosure is not limited thereto.

The second light emitting element LE2 may emit second light. The second light may be green light. For example, the main peak wavelength G-peak of the second light may be disposed at approximately 480 nm to 560 nm, but the present disclosure is not limited thereto.

The third light emitting element LE3 may emit third light. The third light may be blue light. For example, the main peak wavelength B-peak of the third light may be disposed at about 370 nm to 460 nm, but the present disclosure is not limited thereto.

In another embodiment, the first light emitting element LE1, the second light emitting element LE2, and the third light emitting element LE3 may emit light of the same color. Also, a light conversion layer including a light conversion element (e.g., a quantum dot) for converting a color (or a corresponding wavelength band) of light emitted from at least one light emitting element LE from among the first light emitting element LE1, the second light emitting element LE2, and the third light emitting element LE3 into light of another color (or a corresponding wavelength band) may be disposed.

In one or more embodiments, the first light emitting element LE1, the second light emitting element LE2, and the third light emitting element LE3 of each pixel PX may be sequentially disposed along a first direction DX or a second direction DY. In one or more embodiments, the first light emitting elements LE1 may be disposed along the second direction DY. The second light emitting elements LE2 may be disposed along the second direction DY. The third light emitting elements LE3 may be disposed along the second direction DY. For example, in each pixel column extending along the second direction DY, the first light emitting elements LE1, the second light emitting elements LE2, or the third light emitting elements LE3 may be disposed. In addition, the arrangement structure of the pixels PX and the light emitting elements LE provided to the pixels PX may be variously changed according to one or more embodiments.

In one or more embodiment, the light emitting elements LE may be disposed in the display area DA at substantially equal intervals but is not limited thereto. For example, the positions and/or arrangement intervals of the light emitting elements LE may be varied in various ways according to one or more embodiments.

In one or more embodiments, the sizes (e.g., areas) of the light emitting elements LE may be substantially the same as each other. For example, the first light emitting element LE1, the second light emitting element LE2, and the third light emitting element LE3 may have substantially the same sizes. However, the present disclosure is not limited thereto, and the sizes of each of the light emitting elements LE, and/or the areas of the light emitting regions corresponding to the light emitting elements LE, etc. may be varied in various ways according to one or more embodiments.

In one or more embodiments, the light emitting elements LE may have a circular planar shape, but the present disclosure is not limited thereto. For example, the light emitting elements LE may have a rectangular shape or other polygonal, oval, or irregular shape. Further, the light emitting elements LE may have substantially the same planar shape as each other or may have different planar shapes for each group.

The backplane substrate SUB may be a semiconductor circuit board formed by a semiconductor process using a silicon wafer. For example, a silicon wafer may be used as a base material for forming a display panel DP.

The backplane substrate SUB may include pixel circuits PXC, pixel electrodes PXE, and a plurality of interlayer insulating films INS1, INS2, and INS3. For example, at least one light emitting element LE may be provided in each light emitting area EA of the display panel DP, and the backplane substrate SUB may include pixel circuits PXC and pixel electrodes PXE electrically connected to each of the light emitting elements LE disposed in each of the light emitting areas EA.

Each of the pixel circuits PXC may include at least one transistor formed by a semiconductor process. Further, each of the pixel circuits PXC may further include at least one capacitor formed by a semiconductor process. In one or more embodiments, each of the pixel circuits PXC may include a complementary metal-oxide semiconductor (CMOS) circuit formed by using a semiconductor process but is not limited thereto.

In one or more embodiments, a circuit insulating film INS1 may be disposed on the pixel circuits PXC. The circuit insulating film INS1 may be formed of an inorganic film, such as a silicon nitride layer, a silicon oxynitride layer, a silicon oxide layer, a titanium oxide layer, and/or an aluminum oxide layer.

The pixel electrodes PXE may be disposed on the circuit insulating film INS1. The pixel electrodes PXE may be connected to pixel circuits PXC through contact holes penetrating the circuit insulating film INS1. Each of the pixel electrodes PXE may be electrically connected to the pixel circuits PXC. For example, the pixel electrodes PXE and the pixel circuits PXC may be connected in a one-to-one correspondence. Each of the pixel circuits PXC may apply a pixel voltage to the pixel electrode PXE connected thereto. Each of the pixel electrodes PXE may receive a pixel voltage from the pixel circuit PXC. The pixel electrodes PXE may include a conductive material (e.g., a metal material such as aluminum (Al)).

One or more interlayer insulating layers INS2 and INS3 may be disposed on the pixel electrodes PXE and the circuit insulating film INS1. In one or more embodiments, the interlayer insulating layers INS2 and INS3 may include a first interlayer insulating layer INS2 and a second interlayer insulating layer INS3.

The first interlayer insulating layer INS2 may be disposed on the pixel electrodes PXE, and the second interlayer insulating layer INS3 may be disposed on the first interlayer insulating layer INS2.

The first interlayer insulating layer INS2 and the second interlayer insulating layer INS3 may be formed of the same material but are not limited thereto. The first interlayer insulating layer INS2 and the second interlayer insulating layer INS3 may be formed of an inorganic film, such as a silicon nitride layer, a silicon oxynitride layer, a silicon oxide layer, a titanium oxide layer, and/or an aluminum oxide layer.

A light emitting element layer LEL is disposed on the backplane substrate SUB.

The light emitting element layer LEL may include a bottom bonding electrode BBE, an upper bonding electrode UBE, light emitting elements LE, a plurality of element insulating layers INS4 and INS5, a reflective layer RF, a common electrode CE, and a hinge BR. In one or more embodiments, the light emitting element layer LEL may further include a third interlayer insulating layer INS6 disposed on the light emitting elements LE.

For example, the bonding electrode BBE includes a first bonding electrode BBE1 and a second bonding electrode BBE2 sequentially disposed on the second interlayer insulating layer INS3. The upper bonding electrode UBE may include a first upper bonding electrode UBE1 and a second upper bonding electrode UBE2 sequentially disposed on the bonding electrode BBE. A light emitting element LE may be disposed on the upper bonding electrode UBE. The plurality of element insulating layers INS4 and INS5 may be disposed on the second interlayer insulating layer INS3 and cover outer surfaces (e.g., outer peripheral surfaces) of the bottom bonding electrode BBE, the upper bonding electrode UBE, and the light emitting element LE in each emission area and also cover dummy elements DE. The reflective layer RF may be disposed between the plurality of element insulating layers INS4 and INS5 on the side surfaces of the bottom bonding electrode BBE, the upper bonding electrode UBE, and the light emitting element LE.

In one or more embodiments, the light emitting element layer LEL may further include an additional configuration. For example, the light emitting element layer LEL may further include a reflective layer and/or a light blocking layer provided between the light emitting elements LE and/or on the side of the light emitting elements LE.

The first interlayer insulating layer INS2 and the second interlayer insulating layer INS3 have a penetrating contact hole CH. Therefore, the pixel electrode PXE is exposed by the contact hole CH.

A through electrode TRE is disposed inside the contact hole CH. For example, the through electrode TRE may be disposed to fill the contact hole CH and may directly contact the pixel electrode PXE exposed by the contact hole CH. The top surface of the through electrode TRE may be electrically connected to the bottom bonding electrode BBE (BBE1).

The common electrode CE may be disposed on the upper portion of the light emitting elements LE. The common electrode CE may be connected to the light emitting element LE via a hole penetrating the plurality of element insulating layers INS4 and INS5 on the upper portion of the light emitting element LE. In one or more embodiments, the common electrode CE may be supplied with a common voltage through the common electrode connections.

The common electrode CE may include a transparent conductive material that may transmit light. For example, the common electrode CE may be made of indium tin oxide (ITO), indium zinc oxide (IZO), and/or other transparent conductive material. In one or more embodiments, the common electrode CE may function as a cathode electrode (or anode electrode) of the light emitting elements LE.

The hinge BR is disposed between the common electrodes CE between the light emitting elements LE of different regions. The hinge BR may be a material having flexibility and conductivity. The hinge BR may be made of, for example, graphene and/or a conductive polymer material. The hinge BR may be formed of the same material as the first electrode S-10 of the photovoltaic panel SP.

The display panel DP is manufactured in a flat state and is formed to have a curvature by being wrapped around an inner ring (10-I of FIG. 2). Therefore, the hinge BR disposed between the light emitting elements LE while the display panel DP is flat is loosely disposed. Here, ‘loosely disposed’ means that the length of the hinge BR disposed between the light emitting elements LE is longer than the distance between the light emitting elements LE. When the hinge loosely disposed between the light emitting elements LE is wound around the inner ring 10-I while the display panel DP is in a flat state, the gap between the top surfaces of the rigid light emitting elements LE is widened, and the hinge BR is tautly tensioned.

The third interlayer insulating layer INS6 may be disposed on the common electrode CE. The third interlayer insulating layer INS6 may also function as a planarization layer that flattens the lower step. The third interlayer insulating layer INS6 may include an inorganic insulating material such as silicon oxide (SiOₓ), silicon nitride (SiNₓ), silicon oxynitride (SiOₓN_{y}), aluminum oxide (AlₓO_{y}), aluminum nitride (AlN), and/or other insulating materials.

An optical structure (or light-emitting structure), for example, a lens-shaped optical structure LS may be further included on the light emitting element layer LEL.

The lens-shaped optical structure LS may be disposed to overlap the light emitting elements LE. In one or more embodiments, the lens-shaped optical structure LS may be a convex lens-shaped optical structure provided on top of the light emitting elements LE, but the type and/or shape of the optical structure is not limited thereto. By disposing the lens-shaped optical structure LS on top of the light emitting elements LE, the light emission characteristics of the pixels PX may be adjusted and/or improved.

The lens-shaped optical structure LS may be formed of a transparent material so that light incident from the light emitting elements LE may be transmitted. For example, the lens-shaped optical structure LS may be formed of glass, plastic, ceramic, and/or other materials, and may be formed of an optical material having a high refractive index.

The display panel DP may further include additional configurations according to one or more embodiments. For example, the display panel DP may further include a light conversion layer for converting the color and/or wavelength of light emitted from at least some of the light emitting elements LE, and/or a color filter layer for controlling light of a specific color to be emitted from each light emitting region.

The connection member SMP has a structure similar to that of the display panel DP. For example, it may include a bottom bonding electrode BBE, an upper bonding electrode UBE, dummy elements DE, a plurality of element insulating layers INS4 and INS5, a reflective layer RF, a common electrode CE, and a hinge BR.

The dummy element DE has a structure similar to that of the light emitting element LE. For example, the dummy element DE may include a first semiconductor layer SEM1, an active layer MQW, and a second semiconductor layer SEM2 sequentially disposed and/or laminated along the third direction DZ. The width of the dummy element DE may be smaller than that of the light emitting element LE but is not limited thereto. The biggest difference between the dummy element DE and the light emitting element LE is that the dummy element DE is not electrically connected to the common electrode CE. For example, the plurality of element insulating layers INS4 and INS5 of the dummy element DE completely cover the upper portion of the dummy element DE and do not have a separate opening exposing the upper portion of the dummy element DE. As a result, the common electrode CE and the dummy element DE are not electrically connected. In one or more embodiments, as shown in FIG. 6, the dummy elements DE are connected to the adjacent light emitting elements LE by the hinge BR (e.g., the available hinge BR). In one or more embodiments, the dummy elements DE that are adjacent to each other may be connected to each other by the hinge BR (e.g., the available hinge BR).

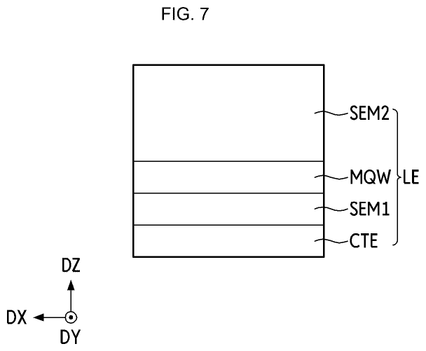

FIG. 7 is a cross-sectional view illustrating a light emitting element according to one or more embodiments.

Referring to FIG. 7, the light emitting element LE may include a first semiconductor layer SEM1, an active layer MQW, and a second semiconductor layer SEM2 sequentially disposed and/or laminated along the third direction DZ. In one or more embodiments, the light emitting element LE may further include a contact electrode CTE provided at one end. For example, the light emitting element LE may further include a contact electrode CTE provided at one end where the first semiconductor layer SEM1 is located.

The light emitting element LE may further include additional layers according to one or more embodiments. For example, the light emitting element LE may further include an electron blocking layer disposed between the first semiconductor layer SEM1 and the active layer MQW, and/or a superlattice layer disposed between the active layer MQW and the second semiconductor layer SEM2.

In one or more embodiments, the light emitting element LE may be an inorganic light emitting element formed of an inorganic material. For example, the light emitting element LE may be an inorganic light emitting diode formed of a nitride-based semiconductor material such as GaN, AlGaN, InGaN, AlInGaN, AlN or InN, a phosphide-based semiconductor material such as GaP, GaInP, AlGaP, AlGaInP, AlP or InP, and/or any other inorganic material.

The contact electrode CTE may be provided and/or formed on one end of the light emitting element LE on which the first semiconductor layer SEM1 is disposed. For example, the contact electrode CTE may be provided and/or formed on one surface of the first semiconductor layer SEM1. The contact electrode CTE may be an electrode for protecting the first semiconductor layer SEM1 and smoothly connecting the first semiconductor layer SEM1 to at least one circuit element, electrode, wiring and/or conductive layer. The contact electrode CTE may include a metal, a metal oxide, and/or another conductive material.

The first semiconductor layer SEM1 may be disposed on the contact electrode CTE. In one or more embodiments, the first semiconductor layer SEM1 may include a nitride-based semiconductor material or a phosphide-based semiconductor material. For example, the first semiconductor layer SEM1 may include a nitride-based semiconductor material including at least one of GaN, AlGaN, InGaN, AlInGaN, AlN, or InN, or a phosphide-based semiconductor material including at least one of GaP, GaInP, AlGaP, AlGaInP, AlP, or InP. The first semiconductor layer SEM1 may also include other materials.

The first semiconductor layer SEM1 may include a semiconductor material doped with a first conductive dopant. For example, the first semiconductor layer SEM1 may be formed of GaN (e.g., p-GaN) doped with a first conductive dopant (e.g., a p-type dopant) such as Mg, Zn, Ca, Se, Ba, etc.

The active layer MQW may be disposed on the first semiconductor layer SEM1. The active layer MQW may emit light by recombination of electron-hole pairs according to an electric signal applied through the first semiconductor layer SEM1 and the second semiconductor layer SEM2. For example, the active layer MQW may be a light emitting layer of a light emitting element LE.

The active layer MQW may include a material having a single or multiple quantum well structure. When the active layer MQW includes a material having a multiple quantum well structure, the active layer MQW may have a structure in which a plurality of well layers and barrier layers are alternately laminated. The active layer MQW may also include different Group III to Group V semiconductor materials depending on the wavelength of the light emitted.

In one or more embodiments, the active layer MQW may include a nitride-based semiconductor material or a phosphide-based semiconductor material. For example, the active layer MQW may include a nitride-based semiconductor material including at least one of GaN, AlGaN, InGaN, InGaAlN, AlN, InN, or AlInN, or a phosphide-based semiconductor material including at least one of GaP, GaInP, AlGaP, AlGaInP, AlP, or InP. In one example, the well layer may be formed of InGaN, and the barrier layer may be formed of GaN or AlGaN, but the present disclosure is not limited thereto. When the active layer MQW includes InGaN, the color of light emitted from the light emitting element LE may be controlled by adjusting the content of indium (In). The active layer MQW may also include other materials.

In one or more embodiments, the active layers MQW of the first light emitting element LE1, the second light emitting element LE2, and the third light emitting element LE3 may emit light of the same color (e.g., blue light). In another embodiment, the active layers MQW of the first light emitting element LE1, the second light emitting element LE2, and the third light emitting element LE3 may emit light of different colors (e.g., red light, green light, and blue light, respectively).

The second semiconductor layer SEM2 may be disposed on the active layer MQW. In one or more embodiments, the second semiconductor layer SEM2 may include a nitride-based semiconductor material or a phosphide-based semiconductor material. For example, the second semiconductor layer SEM2 may include a nitride-based semiconductor material including at least one of GaN, AlGaN, InGaN, AlInGaN, AlN, or InN, or a phosphide-based semiconductor material including at least one of GaP, GaInP, AlGaP, AlGaInP, AlP, or InP. The second semiconductor layer SEM2 may also include other materials.

The second semiconductor layer SEM2 may include a semiconductor material doped with a second conductive dopant. For example, the second semiconductor layer SEM2 may be formed of GaN (e.g., n-GaN) doped with a second conductive dopant (e.g., an n-type dopant) such as Si, Ge, Sn, etc.

In one or more embodiments, the first semiconductor layer SEM1 and the second semiconductor layer SEM2 may have different thicknesses in the thickness direction of the light emitting element LE (e.g., the third direction DZ). For example, the second semiconductor layer SEM2 may have a greater thickness than the first semiconductor layer SEM1 in the thickness direction of the light emitting element LE. Accordingly, the active layer MQW may be disposed closer to the first end (e.g., the p-type end) of the light emitting element LE provided with the first semiconductor layer SEM1 than to the second end (e.g., the n-type end) of the light emitting element LE provided with the second semiconductor layer SEM2.

In one or more embodiments, the light emitting element LE may be a vertical micro-LED that is extended and/or stacked in the third direction DZ. For example, the light emitting element LE may be a micro-LED whose a length in the first direction DX, a length in the second direction DY, and a length in the third direction DZ are each several to several hundred micrometers (μm). In one or more embodiments, the length of the light emitting element LE in the first direction DX, the length in the second direction DY, and the length in the third direction DZ may each be approximately 100 μm or less.

In one or more embodiments, the light emitting element LE may include a substantially vertical side surface as shown in FIG. 6. For example, the light emitting element LE may be patterned through vertical etching and may have a rectangular or square cross-sectional shape in which the width of the top surface and the width of the bottom surface are substantially the same.

The shape of the light emitting element LE may vary depending on the embodiments. For example, the light emitting element LE may have a cross-sectional shape in which the width of the top surface and the width of the bottom surface are different.

In one or more embodiments, the light emitting element LE may have a cross-sectional shape of an inverted taper. For example, the light emitting element LE may have a cross-sectional shape of an inverted trapezoid in which the width of the top surface is wider than the width of the bottom surface.

In one or more embodiments, the light emitting element LE may be disposed on the substrate 110 (e.g., see FIG. 5) such that the first semiconductor layer SEM1 is disposed below the active layer MQW and the second semiconductor layer SEM2 is disposed above the active layer MQW, as shown in FIG. 6. For example, the light emitting element LE may be disposed in each light emitting area EA such that the contact electrode CTE (or the first semiconductor layer SEM1) contacts the upper bonding electrode UBE of FIG. 5 and the second semiconductor layer SEM2 (or another contact electrode provided on the second semiconductor layer SEM2) contacts the common electrode CE. In this case, the common electrode CE may be a cathode electrode.

The structure, material, size, and/or shape of the light emitting element LE are not limited to the above-described embodiments. For example, the structure, material, size, and/or shape of the light emitting element LE may be variously changed according to one or more embodiments.

FIG. 8 is a diagram illustrating a structure of a photovoltaic panel according to one or more embodiments.

Referring to FIG. 8, it may include a first electrode S-10, a second electrode S-20 disposed opposite the first electrode S-10, and a semiconductor layer S-30 and an anti-reflective film S-40 interposed between the first electrode S-10 and the second electrode S-20.

The semiconductor layer S-30 includes a p-type semiconductor S-31 and an n-type semiconductor S-32. The p-type semiconductor S-31 and the n-type semiconductor S-32 convert solar energy into electrical energy. For example, when energy from solar energy enters, electrons and holes generated at the junction of the p-type semiconductor S-31 and the n-type semiconductor S-32 move, so that the p-type semiconductor S-31 has a negative property and the n-type semiconductor S-32 has a positive property. Therefore, electrons in the p-type semiconductor S-31 move to the n-type semiconductor S-32. Through this process, electrons gather in the n-type semiconductor S-32 layer and holes gather in the p-type semiconductor S-31 and are connected to the circuit and converted into electrical energy.

The p-type semiconductor S-31 and the n-type semiconductor S-32 may be formed of silicon.

The silicon semiconductor layer S-30, the first electrode S-10, and the second electrode S-20 are made of flexible materials. In particular, the first electrode S-10, which is disposed on the outermost side, may include a material that is more flexible than the second electrode S-20. The material of the first electrode S-10 may be a material that is flexible and conductive. The first electrode S-10 may be made of, for example, graphene and/or a conductive polymer material. Therefore, the first electrode S-10 may be easily bent to have a curvature.

The anti-reflective film S-40 is disposed on the top of the photovoltaic panel (e.g., on the silicon semiconductor layer S-30). The anti-reflective film S-40 reduces the diffuse reflection of sunlight and increases the amount of light incident on the inside of the photovoltaic panel. The anti-reflective film S-40 may be formed by repeatedly laminating a high-refractive-index material and a low-refractive-index material.

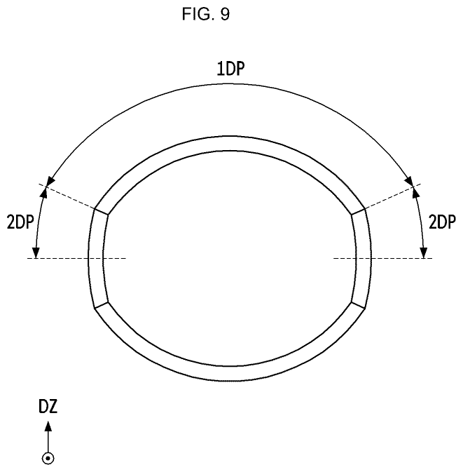

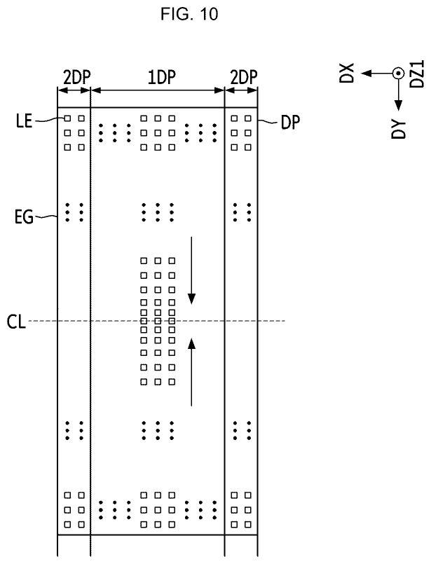

FIG. 9 is a cross-sectional view illustrating a cross-sectional structure of one direction of the wearable display device shown in FIG. 1 according to one or more embodiments. FIG. 10 is a top view illustrating a structure in which the display panel of FIG. 9 is spread out flat.

Referring to FIG. 9, the display panel DP may have a first display area 1DP having a first curvature and a second display area 2DP having a second curvature different from the first curvature. The first curvature may be greater than the second curvature. Accordingly, the second display area 2DP may be curved more gently than the first display area 1DP.

As shown in FIG. 9, the first and second display areas 1DP and 2DP may be curved along the first direction DX with the direction parallel to the first direction DX as the curvature axis. The first and second display areas 1DP and 2DP may have the same distance interval and density of pixels in a state where they have curvature along the first direction DX.

On the other hand, as shown in FIG. 10, when the first and second display areas 1DP and 2DP have a structure in which the display panels are spread out flat, the distance gap and density between the pixels of the first display area 1DP and the second display area 2DP may be different from each other. The gap between pixels disposed in a display area with a relatively large curvature is smaller than the gap between pixels disposed in a display area with a relatively small curvature, and the density of pixels disposed in a display area with a relatively large curvature is larger than the density of pixels disposed in a display area with a relatively small curvature.

When the first direction DX is a row direction and the second direction DY is a column direction, the first display area 1DP in the same column may have a first curvature, and the second display area 2DP may have a second curvature smaller than the first curvature. The second display area 2DP may be disposed on the outer side of the first display area 1DP.

The first gap between pixels disposed in the first display area 1DP may be smaller than the second gap between pixels disposed in the second display area 2DP. Also, the first density between pixels disposed in the first display area 1DP in the same row may be larger than the second density between pixels disposed in the second display area 2DP.

For example, a plurality of pixels in the first display area 1DP are disposed to be spaced (e.g., spaced apart) by a first gap along the first direction DX. The plurality of pixels in the second display area 2DP are disposed to be spaced (e.g., spaced apart) by a second gap along the first direction DX. The first gap is smaller than the second gap. Also, the first density between pixels disposed in the first display area 1DP in the same row may be larger than the second density between pixels disposed in the second display area 2DP.

On the other hand, the first display area 1DP and the second display area 2DP have a wider inter-pixel gap and a smaller pixel density as they go outward from the center line CL in the second direction DY. That is, the first display area 1DP and the second display area 2DP have the narrowest inter-pixel gap and the largest inter-pixel density in the center line CL portion in the second direction DY. For example, in one or more embodiments, a gap between pixels increases and a density of pixels decreases as a distance from the center line CL of the first display area 1DP and the second display area 2DP increases.

The display device according to the embodiments may be applied to various electronic devices. The electronic device according to one or more embodiments includes the display device described above and may further include a module or device having additional functions besides the display device.

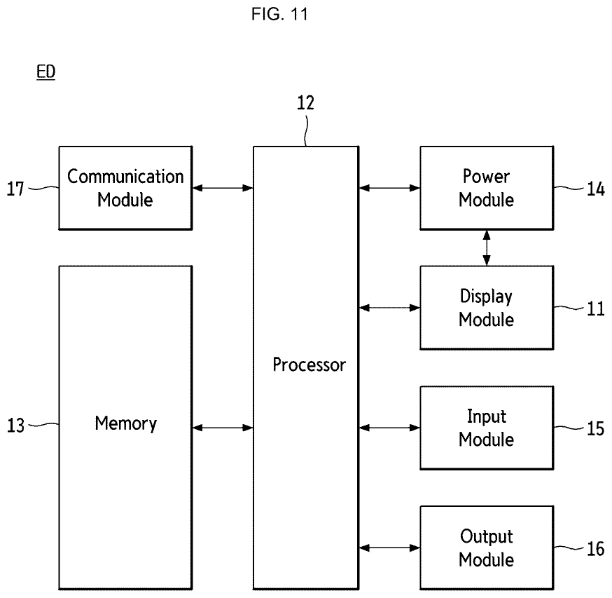

FIG. 11 is a block diagram of an electronic device according to one or more embodiments of the present disclosure.

Referring to FIG. 11, the electronic device ED according to one or more embodiments of the present disclosure may include a display module 11, a processor 12, a memory 13, a power module 14, an input module 15, an output module 16, and a communication module 17.

The processor 12 may include at least one of a central processing unit (CPU), an application processor (AP), a graphic processing unit (GPU), a communication processor (CP), an image signal processor (ISP), or a controller.

The memory 13 may store data information necessary for the operation of the processor 12 or the display module 11. When the processor 12 executes an application stored in the memory 13, an image data signal and/or an input control signal is transmitted to the display module 11, and the display module 11 can process the received signal and output image information through a display screen.

The power module 14 may include a power supply module such as, for example a power adapter and/or a battery, and a power conversion module that converts the power supplied by the power supply module to generate power necessary for the operation of the electronic device ED.

At least one of the components of the electronic device ED according to the embodiments of the present disclosure may be included in the display device 10 according to the embodiments of the present disclosure. In addition, some modules of the individual modules functionally included in one module may be included in the display device 10, and other modules may be provided separately from the display device 10. For example, the display device 10 may include the display module 11, and the processor 12, the memory 13, and the power module 14 may be provided in the form of other devices within the electronic device ED other than the display device 10.

In concluding the detailed description, those skilled in the art will appreciate that many variations and modifications can be made to the embodiments without substantially departing from the principles and scope of the present disclosure. Therefore, the embodiments of the present disclosure are used in a generic and descriptive sense only and not for purposes of limitation.

What is claimed is:

1. A wearable display device comprising:
a top cover having a ring shape or a cylindrical shape with respect to a curvature axis parallel to a first direction;
a display member having a curvature along an inner side of the top cover and having a plurality of light emitting elements;
a battery member in an inner side of the top cover and having a curvature, the battery member comprising a photovoltaic panel; and
a connection member in the inner side of the top cover and having a curvature, the connection member being located between the display panel and the photovoltaic panel, and comprising a plurality of dummy elements.

2. The device of claim 1, wherein the plurality of light emitting elements are connected to each other by a hinge, and wherein the hinge comprises a material that is flexible and conductive.

3. The device of claim 2, wherein the light emitting element comprises a first semiconductor layer doped with a first conductive dopant, a second semiconductor layer doped with a second conductive dopant, and an active layer disposed between the first semiconductor layer and the second semiconductor layer,
wherein the display member further comprises a common electrode on the light emitting element, and
wherein the hinge is connected to the common electrode.

4. The device of claim 2, wherein the plurality of dummy elements are connected to each other by the hinge, and wherein the dummy elements are connected to the adjacent light emitting elements by the available hinge.

5. The device of claim 4, wherein the plurality of dummy elements comprises a first semiconductor layer doped with a first conductive dopant, a second semiconductor layer doped with a second conductive dopant, and an active layer between the first semiconductor layer and the second semiconductor layer.

6. The device of claim 1, wherein the battery member further comprises a rechargeable battery.

7. The device of claim 2, wherein the photovoltaic panel is in the inner side of the top cover and has a curvature, the photovoltaic panel comprising a first electrode, a second electrode located opposite the first electrode, a semiconductor layer interposed between the first electrode and the second electrode, and an anti-reflective film on the semiconductor layer and adjacent to the top cover.

8. The device of claim 7, wherein the first electrode and the second electrode comprises a conductive material.

9. The device of claim 8, wherein the first electrode comprises a same material as the hinge.

10. The device of claim 1,
wherein the display member comprises a first display area having a first curvature and a second display area having a second curvature,
wherein the first curvature is greater than the second curvature.

11. The device of claim 10, wherein a first gap between pixels of the first display area in a same column is smaller than a second gap between pixels of the second display area.

12. The device of claim 10, wherein a density of pixels of the first display area in a same column is greater than a density of pixels of the second display area.

13. The device of claim 10, wherein a gap between pixels of the display member increases and a density of the pixels decreases as a distance from a center line of the first display area and the second display area increases.

14. The device of claim 1, further comprising an inner ring having a ring shape or a cylindrical shape with respect to the curvature axis.

15. The device of claim 14, wherein the display member and the battery member are wound around the inner ring.

16. The device of claim 3, wherein the common electrode comprises a transparent conductive material.

17. The device of claim 3, wherein the light emitting element further comprises:
a first insulating layer around side surfaces of the light emitting element and a connection electrode;
a reflective layer on the side surfaces of the light emitting element; and
a second insulating layer around the side surfaces of the light emitting element and the connection electrode, the second insulating layer being on the reflective layer and the first insulating layer.

18. The device of claim 3, wherein the display member further comprises a lens-shaped optical structure on a light emitting element layer on the light emitting element.

19. An electronic device comprising:
a memory;
a processor configured to execute an application stored by the memory; and
a wearable display device,
wherein the wearable display device comprises:
a top cover having a ring shape or a cylindrical shape with respect to a curvature axis parallel to a first direction;
a display member having a curvature along an inner side of the top cover and having a plurality of light emitting elements;
a battery member in an inner side of the top cover and having a curvature, the battery member comprising a photovoltaic panel; and
a connection member in the inner side of the top cover and having a curvature, the connection member being located between the display panel and the photovoltaic panel, and comprising a plurality of dummy elements.

20. The device of claim 19,
wherein the display member comprises a first display area having a first curvature and a second display area having a second curvature,
wherein the first curvature is greater than the second curvature.
